(19) United States
(12) Patent Application Publication
(10) Pub. No.: US 2026/0163329 A1
(43) Pub. Date: Jun. 11, 2026

(54) OPTICALLY PUMPED SEMICONDUCTOR LASER USING GALLIUM AND NITROGEN CONTAINING DIODE LASER SOURCE AND MODULE

(71) Applicant: Kyocera Corporation, Kyoto (JP)

(72) Inventors: James W. Raring, Santa Barbara, CA (US); Malcolm Minty, Los Gatos, CA (US); Matthew Philpott, Portland, OR (US); Eric Goutain, Fremont, CA (US); Dennis Van Den Broeck, Raleigh, NC (US); Meng Zhang, San Jose, CA (US); Terry Towe, Goleta, CA (US)

(73) Assignee: Kyocera Corporation, Kyoto (JP)

(21) Appl. No.: 19/381,638

(22) Filed: Nov. 6, 2025

Related U.S. Application Data
(60) Provisional application No. 63/718,380, filed on Nov. 8, 2024.

(51) Int. Cl. H01S 5/04; H01S 5/024; H01S 5/183; H01S 5/42

(52) U.S. Cl. CPC H01S 5/041; H01S 5/02476; H01S 5/18358; H01S 5/18366; H01S 5/18397; H01S 5/426

(57) ABSTRACT

An optically pumped solid state laser (OPSL) module is disclosed. A submount unit is provided having raised wedged portion(s) to accommodate at least one gallium and nitrogen (GaN) containing pump laser diode. The at least one GaN pump laser diode is mounted on a wedge such that the light emission points at a downward angle, through beam shaping optics, and onto a GaN gain chip that is placed on a centerpiece platform representing a space between the lower portion of the one or more wedged portion(s). The gain chip is made of a series of spacer and active regions, all epitaxially formed, so that upon pumping from the pump laser diode(s), there is photonic emission from the gain chip. The gain chip spacer and active regions are selected based upon the desired wavelength output. Each active region may be spaced apart based on a half-wavelength metric.

### CROSS REFERENCE TO RELATED APPLICATIONS

The present application claims priority to U.S. Provisional Application No. 63/718,380, filed Nov. 8, 2024, the contents of which are incorporated herein by reference in their entirety for all purposes.

### BACKGROUND

An optically pumped semiconductor laser (“OPSL”) is a type of laser that uses a semiconductor gain medium, which is excited (or “pumped”) by an external light source—typically another laser diode. Unlike traditional diode lasers, where electrical current directly stimulates light emission, OPSLs rely on optical pumping to achieve lasing.

### SUMMARY

OPSL devices provide a laser solution for when custom wavelength laser diodes are needed, and a ready supply of custom wavelength laser diodes may not exist. Some laser applications may benefit from using small-footprint laser diodes, but the applications may require unusual wavelengths: for example about 485 nm blue or about 532 nm green. Other applications may require higher power output for a single beam. Other laser diode applications may have still further laser requirements for which a ready supply of laser diodes may not exist. The OPSL modules described herein provide a solution for each of these and other applications. For example, in accordance with an embodiment, an OPSL module includes a gain chip having a plurality of gallium and nitrogen containing thin films, the gain chip having a first side and an opposing second side; a reflective mirror coupled to the second side of the gain chip; one or more gallium and nitrogen containing laser diode sources positioned to provide optical pumping to said gain chip so as to generate a photonic emission output from the first side of the gain chip; a coherence-generating reflecting mirror positioned relative to the gain chip so as to receive the photonic emission output from the first side of the gain chip such that the photonic emission incident on the coherence-generating reflecting mirror interacts with the reflective mirror so as to generate a coherent photonic emission emitted from the coherence-generating reflecting mirror; a heat conducting member coupled to the gain chip; and optics arranged to gather and transmit the coherent photonic emission.

In an embodiment, the reflective mirror includes a distributed Bragg reflector (DBR).

In another embodiment, the reflective mirror and the coherence-generating reflecting mirror are arranged so that the photonic emission reflected by the reflective mirror is incident on and reflected by the coherence-generating reflecting mirror.

In another embodiment, the reflective mirror is a coating of one or more reflective materials. The one or more reflective materials may include at least one of silicon dioxide, hafnia, titania, tantalum pentoxide, or zirconia.

In another embodiment, the heat conducting member is a heat sink.

In another embodiment, the OPSL module includes a plurality of gain chips and a plurality of laser diode sources, wherein the plurality of gain chips are arranged in an array and each of the plurality of laser diode sources pumps one of the plurality of gain chips.

In yet another embodiment, the OPSL module also includes a submount unit having a raised wedge portion and a center portion, wherein the gain chip is arranged on the center portion and at least one of the gallium and nitrogen containing laser diode sources is arranged on the raised wedge portion.

In accordance with another embodiment, an OPSL module includes a submount unit having one or more raised wedge portions and a center portion, a surface of each of the raised wedge portions extending at a positive angle to a surface of the center portion, and the center portion extending from a lower portion of the raised wedge portions; one or more gallium and nitrogen containing pump laser diodes, each of the gallium and nitrogen containing pump laser diodes mounted on a different one of the raised wedge portions; a gallium and nitrogen containing gain chip arranged on the center portion, the gallium and nitrogen containing gain chip comprising a series of alternating spacer and active regions so that optical pumping from the gallium and nitrogen containing pump laser diodes generates a photonic emission from the gallium and nitrogen containing gain chip, the spacer and active regions configured to provide a desired wavelength of the photonic emission, each active region spaced from others of the active regions based on a half-wavelength metric; and one or more beam shaping optics each associated with one of the gallium and nitrogen containing pump laser diodes, wherein each of the beam shaping optics is arranged so that an emission from one of the gallium and nitrogen containing pump laser diodes mounted on one of the raised wedge portions extends through the beam shaping optic and onto an upper surface of the gallium and nitrogen containing gain chip.

In an embodiment, an upper surface of the center portion is substantially planar.

In another embodiment, the positive angle is an obtuse angle of about 145 degrees.

In another embodiment, a bottom surface of the gallium and nitrogen containing gain chip includes a reflector coating.

In another embodiment, a bottom surface of the gallium and nitrogen containing gain chip includes a distributed Bragg reflector (DBR).

In another embodiment, the OPSL module also includes a mirror arranged so that the photonic emission from the gallium and nitrogen containing gain chip emanates towards the mirror, and the mirror is configured to reflect the photonic emission to generate a coherent emission that is emitted from the mirror as a laser beam.

In another embodiment, the gallium and nitrogen containing gain chip is configured to produce coherent light at a wavelength of between about 385 nm and 650 nm.

In another embodiment, the gallium and nitrogen containing pump laser diodes are edge-emitting ridge laser diodes.

In another embodiment, the OPSL module also includes a heat sink coupled to the submount unit.

In another embodiment, the OPSL module also includes a heat spreader coupled to the gallium and nitrogen containing gain chip.

In another embodiment, the center portion includes a reflector configured to reflect the photonic emission.

In another embodiment, the center portion includes a thermally conductive member.

In another embodiment, the OPSL module also includes a means for tuning a wavelength of the photonic emission.

In another embodiment, the OPSL module also includes an amplifier configured to amplify an emitted laser beam.

In another embodiment, the OPSL module also includes a housing with brackets configured to hold the OPSL module.

In another embodiment, the OPSL module also includes a housing with walls and a transparent window.

In another embodiment, the OPSL module also includes a window and an upper mirror, the window configured to allow the photonic emission to pass therethrough, and the upper mirror arranged so that the photonic emission that passes through the window emanates towards the upper mirror, and the upper mirror is configured reflect the photonic emission to generate a coherent emission that is emitted from the mirror as a laser beam.

In another embodiment, the OPSL module also includes at least two raised wedge portions each having one of the gallium and nitrogen containing pump laser diodes mounted thereto.

In another embodiment, the OPSL module also includes an interposer configured as at least one of a heat spreader or a mirror, wherein the interposer is arranged between center portion and the gallium and nitrogen containing gain chip.

In another embodiment, the submount unit includes a submount base that supports the raised wedge portions and the center portion.

In another embodiment, the submount unit includes a shelf portion coupled with a bracket configured to apply a force to the raised wedge portions.

In another embodiment, the OPSL module also includes a housing with walls and a window, wherein the window is configured to reflect the photonic emission to generate a coherent emission that is emitted from the window as a laser beam.

In another embodiment, the gallium and nitrogen containing gain chip includes a top reflective coating and a bottom reflective coating to generate a coherent light emission that is emitted as a laser beam.

In another embodiment, the spacer regions comprise at least one of GaN, AlGaN or InGaN, and the active regions comprise at least one of InGaN, GaN, AlGaInN, or AlGaN.

In another embodiment, the gallium and nitrogen containing gain chip includes a window layer having a lower refractive index than the barrier and active regions.

In another embodiment, the gallium and nitrogen containing gain chip includes a distributed feedback (DFB) grating structure.

In another embodiment, the OPSL module also includes a lens for collimation and/or beam shaping of an output beam.

In another embodiment, a monolithic surface mount device comprises the OPSL module.

In yet another embodiment, an integrated surface mount device comprises the OPSL module.

In accordance with yet another embodiment, an OPSL module includes a submount unit having a plurality of raised wedge portions and a center portion, a surface of each of the raised wedge portions extending at a positive angle to a surface of the center portion, and the center portion extending from a lower portion of the raised wedge portions; a plurality of gallium and nitrogen containing pump laser diodes, each of the gallium and nitrogen containing pump laser diodes mounted on a different one of the raised wedge portions; an N×M array of gallium and nitrogen containing gain chips arranged on the center portion, each of the gallium and nitrogen containing gain chips comprising a series of alternating spacer and active regions so that optical pumping from the gallium and nitrogen containing pump laser diodes generates a photonic emission from the gallium and nitrogen containing gain chips, the spacer and active regions configured to provide a desired wavelength of the photonic emission, each active region spaced from others of the active regions based on a half-wavelength metric; and one or more beam shaping optics each associated with one of the gallium and nitrogen containing pump laser diodes, wherein each of the beam shaping optics is arranged so that an emission from one of the gallium and nitrogen containing pump laser diodes mounted on one of the raised wedge portions extends through the beam shaping optic and onto an upper surface of at least one of the gallium and nitrogen containing gain chips.

In an embodiment, the N×M array of gallium and nitrogen containing gain chips includes at least two gallium and nitrogen containing gain chips, and N is at least one and M is at least one.

In another embodiment, laser beams from the N×M array of gallium and nitrogen containing gain chips are phase locked to generate a coherent beam.

In another embodiment, laser beams from the gallium and nitrogen containing pump laser diodes are spectrally combined with the N×M array of gallium and nitrogen containing gain chips.

In yet another embodiment, laser beams from each of the N×M array of gallium and nitrogen containing gain chips are separated in wavelength by at least about 1 nm, and the laser beams are spectrally combined.

### BRIEF DESCRIPTION OF THE DRAWINGS

FIGS. 1-3 are simplified diagrams of OPSL devices that use at least one laser diode to optically pump a gallium and nitrogen containing gain chip in accordance with some embodiments.

FIG. 4 is a simplified diagram of an N×M array of OPSL elements in accordance with some embodiments.

FIG. 5 is a simplified diagram of an N×M array of OPSL elements arranged to receive pump light at a bottom surface in accordance with some embodiments.

FIG. 6 is a simplified diagram of a OPSL module in accordance with some embodiments.

FIG. 7 is a simplified diagram of an OPSL element in accordance with some embodiments.

FIG. 8 is a simplified diagram of an OPSL module in accordance with some embodiments.

### DESCRIPTION

This disclosure relates to OPSL devices and systems wherein at least one gallium and nitrogen containing laser diode is used as the pump source.

This disclosure also relates to OPSL modules wherein a housing includes a non-horizontal support member for at least one gallium and nitrogen containing laser diode to use as a pump source for a gallium and nitrogen containing gain chip supported at an angle relative to the at least one pump source.

As illustrated in the appended drawings, the disclosure of which is hereby incorporated in its entirety for all purposes, various embodiments and configurations of the OPSL pumped with laser diodes are shown.

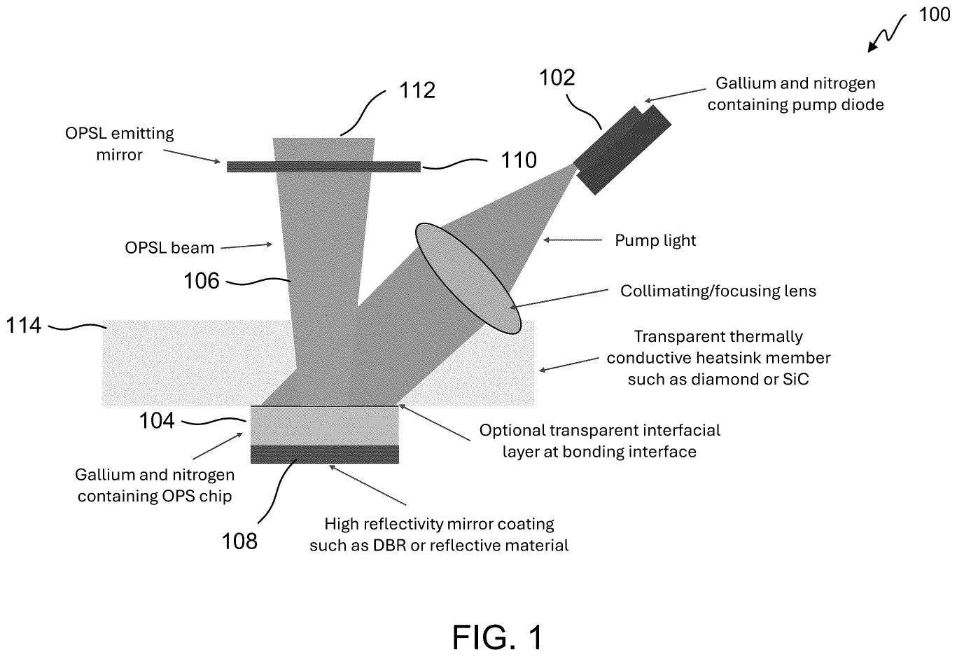

FIGS. 1-3 shows novel OPSL devices 100, 200, 300 that use at least one laser diode 102, 202, 302 to optically pump a gallium and nitrogen containing gain chip 104, 204, 304 to enable the production of coherent light 106, 206, 306 in a range of approximately 385 nm to 650 nm. The novel OPSL 104, 204, 304 in some embodiments, includes a quantum well structure for electron-hole recombination formed using thin films of variously doped materials including gallium and nitrogen and other materials depending on desired wavelength and light characteristics. The quantum well structure and other device design details provide an emission wavelength which may span visible light emission options, or approximately 385 nm to 650 nm.

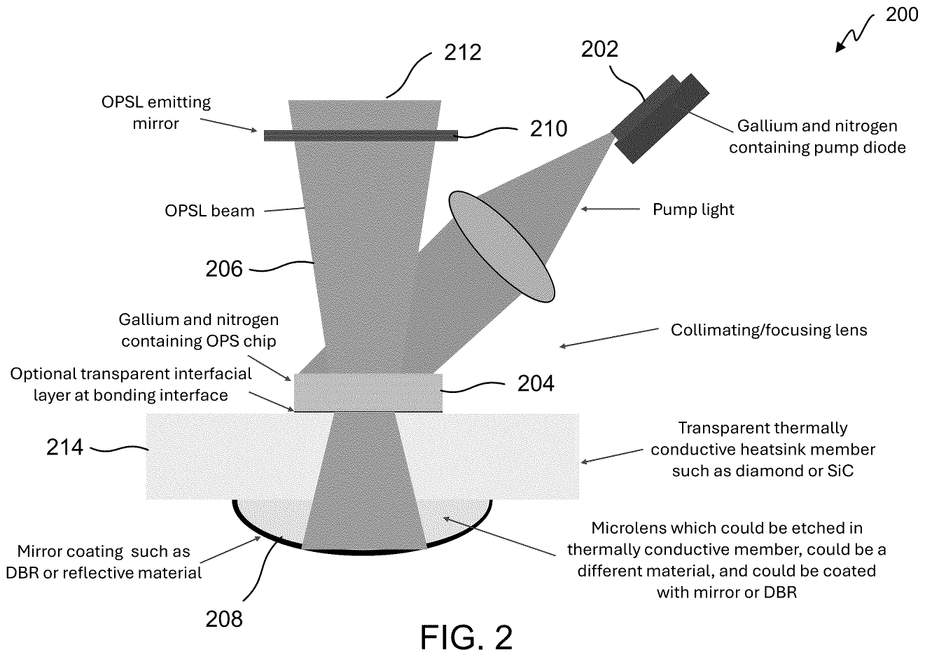

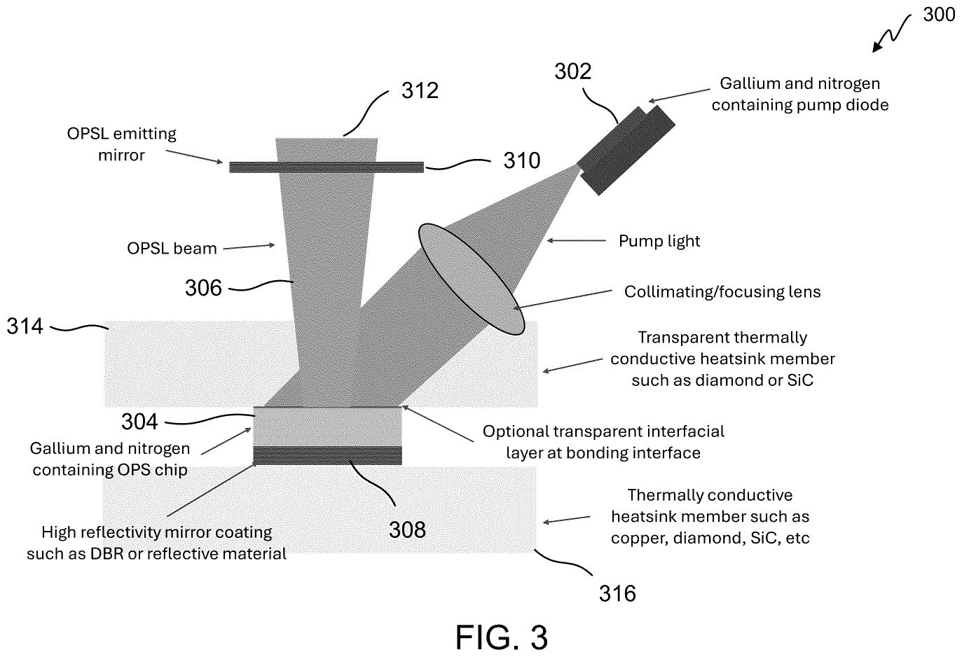

If positioned horizontally, the OPSL has a top surface and a bottom surface. In some embodiments, one of the surfaces, preferably the bottom surface, includes a reflector coating which may include a distributed Bragg reflector (“DBR”). FIGS. 1 and 3 provide examples of OPSL devices 100, 300 with a reflective coating 108, 308 on a bottom surface of the OPSL 104, 304, and FIG. 2 provides an example of a reflective coating 208 on a lens. The top surface can emanate light emission out of the OPSL toward a reflector 110, 210, 310 which may be a mirror. The mirror reflector 110, 210, 310 includes a coating (e.g., a material comprising at least one of silicon dioxide, hafnia, titania, tantalum pentoxide, or zirconia) so as to cause a desired amount of light reflection back to the reflective coating 108, 208, 308 to generate a coherent emission, but the coating can allow the coherent emission to exit out of the reflector 110, 210, 310 away from the OPSL so as to form a laser beam 112, 212, 312 that can be used for a variety of purposes.

The OPSL 104, 204, 304 is pumped using one or more light sources 102, 202, 302, preferably gallium and nitrogen-based laser diodes designed to produce coherent light at a targeted visible light wavelength which may be within the range of approximately 385 nm to 650 nm. The light source laser diode(s) may be edge-emitting Fabry-Perot style ridge laser diodes which may be multi-mode, or may be narrow width and may be further enhanced with a structure to increase the light source power output such as distributed feedback (“DFB”). In some configurations, the light source laser diode(s) may be a vertical cavity surface-emitting laser (“VCSEL”) or other type of laser diode(s) capable of pumping the OPSL.

Both the OPSL 104, 204, 304 and the pump source laser diodes 102, 202, 302 may be manufactured using a transfer process that starts with a bulk gallium and nitrogen containing substrate (“GaN substrate”) on which various thin films are grown including using epitaxial deposition to form a thin film stack. The bulk GaN substrate may be of a c-plane (polar) crystalline orientation. In some embodiments, the bulk GaN substrate may be of a nonpolar or semipolar crystalline orientation. The crystalline orientation of the bulk GaN substrate may be selected depending on desired polarization and optical gain properties. Though polar crystalline orientation is known for providing spontaneous polarization, if increased polarization extinction ratio (“PER”) is desired, a nonpolar or semipolar GaN substrate crystalline orientation may be selected. If VCSEL pumping lasers are used, forming the VCSELs on a polar GaN substrate may not result in high polarization due to the in-plane crystallographic symmetry. Using a nonpolar or semipolar GaN substrate instead may provide improved optical gains with greater PER-PER which may be greater than 90%, 99% or 99.9%. Polarization effects for the OPSL may be controlled using optics such as a cavity feedback mirror or other internal cavity optical elements such as birefringent filter.

The thin film stack is then removed from the bulk gallium and nitrogen substrate and transferred to a different substrate which may be silicon carbide, silicon, diamond, aluminum nitride, copper, or another kind of material that is capable of conducting heat.

Exemplary transfer processes are generally described in the following patents, the contents of which are incorporated herein by reference for all purposes:
“Manufacturable Laser Diode Formed on C-Plane Gallium and Nitrogen Material”, U.S. Pat. No. 11,569,637, filed Jan. 7, 2021;
“Manufacturable Laser Diode”, U.S. Pat. No. 9,379,525, filed Jun. 23, 2014; and
“Manufacturable Thin Film Gallium and Nitrogen Containing Devices Integrated with Silicon and Electronic Devices”, U.S. Pat. No. 10,854,776, filed Feb. 20, 2020.

The pump lasers may be more generally described in the above-listed patents, as well as the following patents, the contents of which are incorporated herein by reference for all purposes:
“Optical Device Structure Using GaN substrates and Growth Structures for Laser Applications”, U.S. Pat. No. 11,862,937, filed Nov. 10, 2020; and
“Narrow Sized Laser Diode”, U.S. Pat. No. 9,088,135, filed Jun. 27, 2013.

Thermal management can be important for the OPSL. Having the OPSL structure bonded to a thermally conductive substrate (it may be said “OPS chip”), such as silicon carbide, aids thermal management (see transparent heat sinks 114, 214, 314 in FIGS. 1-3 and heat sink 316 in FIG. 3). The OPS chip may include a DBR portion. The DBR portion may be coupled to a thermally conductive heat sink (see heat sink 316 in FIG. 3). In some embodiments, the OPSL structure itself may or may not have a DBR or mirrored portion directly fabricated thereon on the bottom side, and/or a transparent thermally conductive heat sink may be coupled to the bottom side to draw heat away from the OPSL (see transparent heat sink 214 in FIG. 2). The opposing side of the heat sink may be coupled to or incorporate a lens to facilitate collimation or beam focus (see lens 208 in FIG. 2). The lens may include a mirror or reflector coating such as DBR or reflective material to cause light to bounce back toward the OPSL and ultimately out of the OPSL top and into an emitting mirror.

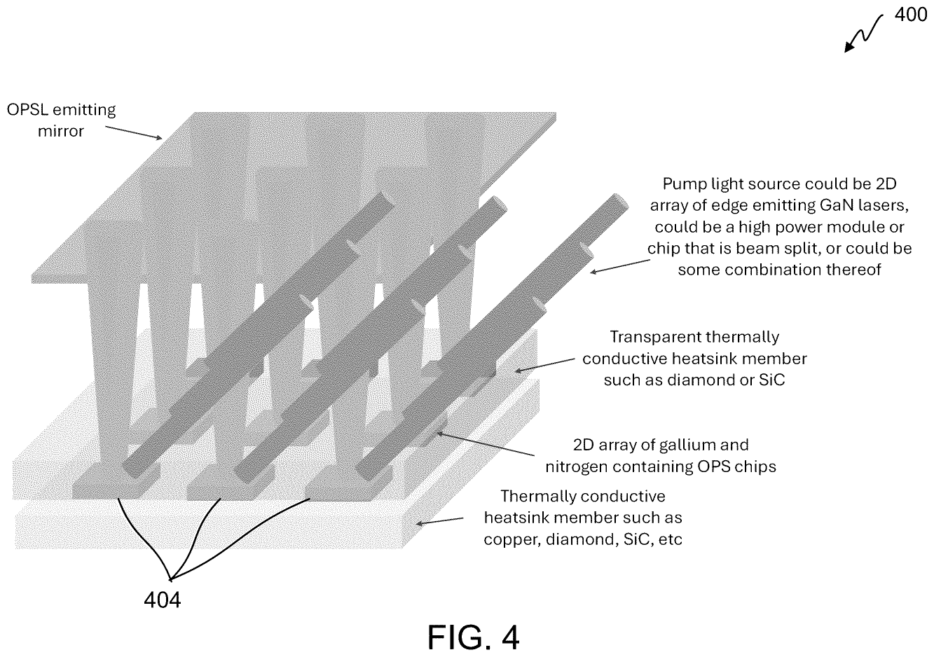

The OPSL configuration may include a single OPSL pumped with one or more pump sources. In some configurations, such as the example shown in FIG. 4, there may be an N×M array 400 of OPSL elements 404 all coupled to a thermally conductive member. In some embodiments, the N×M array of OPSL elements 404 includes at least two OPSL elements, where N is at least one and M is at least one. N may be equal to M in some embodiments and not equal to M in other embodiments. There may be multiple OPSL pump sources. The pump sources may also be in an array, either their own array configuration or may be an array that matches the array of OPSL elements.

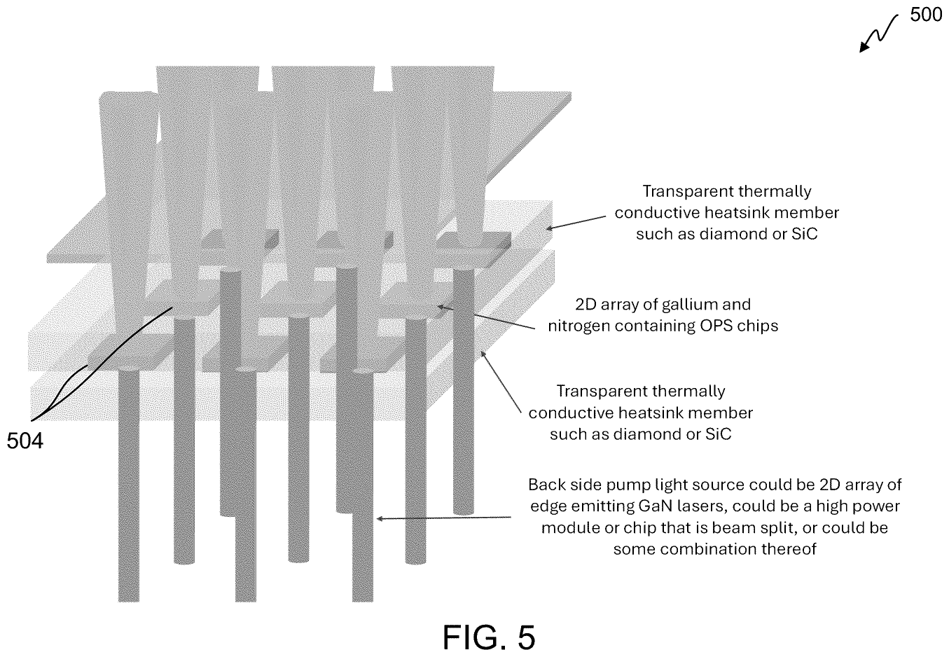

The pump light source may be positioned to impart light emission to the top surface of the OPSL, which may reflect from a back-side reflector so as to create a light source emitting outward from the top of the OPSL. In some embodiments, the pump light source may be positioned to impart light emission to the bottom surface of the OPSL such that the light would emit through the OPSL and out of the top of the OPSL to an emitting mirror. FIG. 5 shows an example of an N×M array 500 of OPSL elements 504 arranged in this manner.

The wavelength of the output light from the OPSL may be set shorter or longer than the wavelength of the pump light source. The output light from the OPSL may be used in a variety of applications depending on the wavelength and output power requirements. The output wavelength can be further adjusted using known methods such as wavelength tuning which may include frequency doubling or tripling, using gratings, wavelength modifying crystals and other materials, or other methods. The OPSL may include a wavelength modulator if fine-tuning of the wavelength is used. The output wavelength of the OPSL may be modified to a higher wavelength as warranted by the application. For example, a multi-stage pumping scheme with staged wavelength pump diodes may enable the higher output wavelength from the OPSL. There may be an amplifier coupled to the OPSL so that the OPSL output beam pumps the amplifier to achieve amplification as well as higher wavelength depending on the design of the amplifier. The output light from the OPSL may enter a wavelength converter such as a crystal.

The pump source may be configured to optically pump the N×M array of OPSL elements, wherein the pump source includes an array of collimated diode lasers which may be configured to correspond with the N×M array of OPSL elements.

Each OPSL element may generate a laser beam with about 0.1 W to about 10 W of power or more.

The OPSL laser beams may be phase locked to generate a coherent beam combined laser source of an N×M array of OPSL elements with an output power of about 1 W to about 10,000 W.

The phase locked N×M array OPSL laser source may be spectrally beam combined with 1 to 100 OPSL elements to generate a combined laser source having an output power of about 10 W to about 1,000,000 W.

In some embodiments, each of the laser beams in the N×M array of OPSL elements is separated in wavelength by at least 1 nm, and the laser beams may be spectrally beam combined to generate a single laser beam comprising the N×M array of laser beams to generate an output power of about 1 W to about 10,000 W.

The spectrally beam combined N×M array of OPSL laser source may be coherently beam combined with 1 to 100 OPSL laser sources to generate a combined laser source with an output power of about about 10 W to about 1,000,000 W, which may be useful for a number of high power applications including nuclear fusion and directed energy applications.

Thermal management may include placing heat spreaders on both sides of the OPSL. The OPSL may be immersed in liquid (for example water, ethylene glycol or other high heat capacity liquid) so that the liquid pulls heat away from the OPSL.

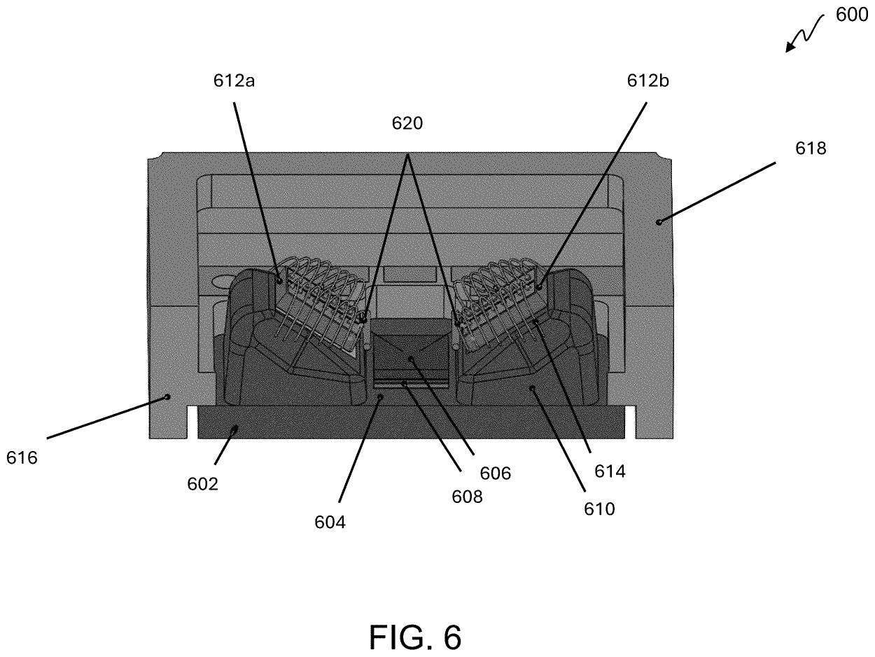

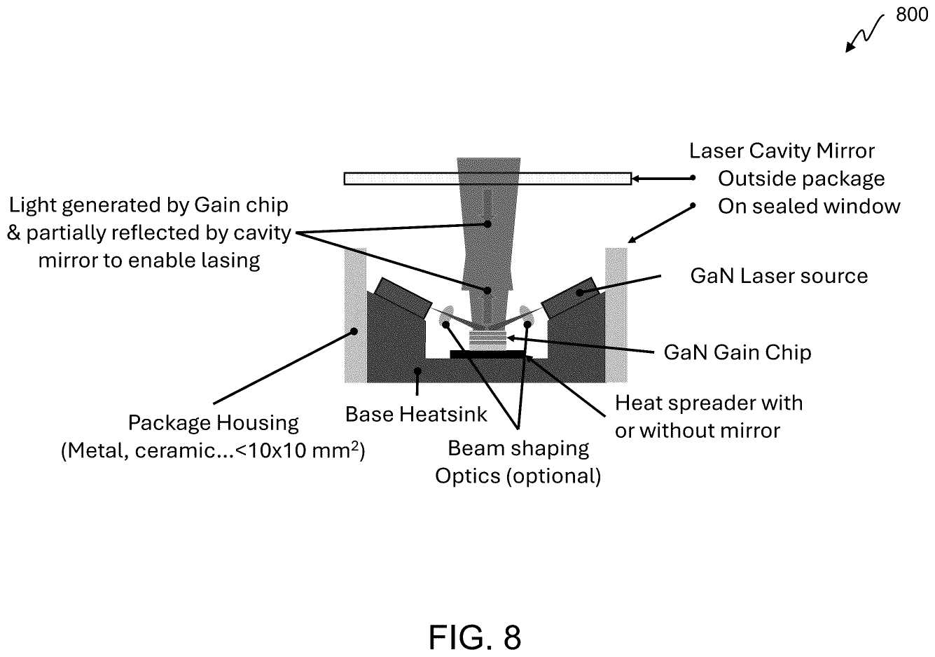

Referring to FIG. 6, an exemplary OPSL module 600 is shown. The OPSL module is generally represented by a surface mount device (“SMD”) which may be a monolithic unit or may be an integration of pieces, wherein the bottom of the SMD may be flat for coupling to a heat sink and/or mounting to a board or holder. The SMD may include a flat, horizontal center portion on which the OPSL gain chip and gain chip bottom mirror and heat spreader may be mounted. The SMD may also include wedged mounts for the downward-angled pump lasers to impart light emission onto the gain chip. The SMD may be encased in package housing with a support frame and brackets to hold the SMD in place. The package housing may include walls that rise up to a distance above the upper portion of the pump laser wedge. The package housing may be covered by a hermetic cap or window coupled to the top of the walls. The walls enclose an interior portion and support a transparent window and, in some embodiments, an upper mirror to generate a lasing emission from the gain chip. An example 800 is shown in FIG. 8.

Coupled to the SMD is at least one laser diode source which may be a gallium and nitrogen containing (“GaN”) ridge laser diode. The GaN laser diode may be configured so as to emit ultraviolet, violet, blue, green or yellow light in a single or multi-mode. In some embodiments, the GaN laser diode may be mounted on a wedge submount and electrically coupled to a power source (not shown) with electrical voltage controllably delivered to the laser via wirebonds. There may be at least one wedge submount but preferably there are at least two, with this particular configuration capable to provide up to six or more pump laser diodes each on its own wedge submount. For purposes of this description, assume that there are two wedge submounts.

The wedged submount may be angled from horizontal, to deliver laser light emission to a center portion (or centerpiece platform). The preferred angle from horizontal may be in a range of approximately 25 degrees (or approximately 155 degrees from a surface of the center portion) to approximately 45 degrees (or approximately 135 degrees from the surface of the center portion) or may be a shallower angle or steeper angle, depending on the design for desired light emission angle from the one or more pump lasers onto the gain chip.

Each of the wedged submounts may include beam shaping optics located at the emission side of the pump lasers, if necessary, based on the desired light characteristics of the GaN lasers, so as to change the distribution profile of the light emitting from the pump lasers according to a desired beam shape for hitting the gain chip. The wedged submounts are angled such that they point toward a center portion which comprises a horizontal submount (or substantially planar surface) on which the GaN gain chip is held.

The gain chip may be a square, rectangular, triangular or other geometric shape with a top side, out of which light may emit upward and away from the submount. The gain chip may be coupled to an interposer with a substantially flat bottom that may function as a mirror, a heat spreader, or both. The interposer may include a monolithic or composite piece made to achieve good thermal conduction such as copper, aluminum, graphite, or other thermally conductive material or composite so as to draw heat away from the bottom of the gain chip. The interposer may be coated on the surface facing the gain chip with a mirror to reflect light that may otherwise emit out of the bottom, to redirect the light toward the opposite side of the gain chip.

The gain chip interposer may be coupled to a gain chip platform, which may be a flat, horizontal portion that represents the center portion defined by the lower edges of the wedged submounts. The gain chip platform may be made of heat spreading material integrated into the submount base heatsink which simultaneously serves as a base and a heatsink. The submount base supports the gain chip platform as well as the wedged submounts such that the wedged submounts, gain chip platform and the submount base are integrated together as separate pieces or may be part of a monolithic molded piece which supports the components and thermally conducts heat away, wherein the integrated parts or monolithic piece may be referred to as OPSL submount.

The submount base may include a shelf portion jutting outward to accept a corresponding bracket portion of a package housing support frame. The brackets may apply force sideways onto the wedged submount outer edges so as to firmly set the submount base in place. The package housing support frame may include a wall that defines the outer perimeter of the OPSL submount. The wall may rise up to a height higher than the highest portion of the submount with the mounted pump lasers. A window may be placed on the topside of the wall to enable transparent light output while protecting the submount and components from the ambient. The window may be a mirror or the mirror may be a separate piece attached to the window effective so as to reflect light emitting from the gain chip such that, with reflection from the topside mirror and the gain-chip side mirror, the light becomes coherent. The window may be by itself or may be coupled to a hermetic seal.

Note that as an alternative embodiment, the top of the submount package may not include a mirror at all. Instead, the gain chip may have reflective coatings on both top and bottom sides of the chip, the emitting side being less reflective, the non-emitting side being more reflective, so as to create coherency in the light emission. As an alternative to a mirror on the bottom side, there may be a feedback grating, for instance a DFB (distributed feedback) or DBR (distributed Bragg reflector) grating so as to adjust the photon absorption in the active bandgap region. Persons skilled in the art may elect various approaches to providing the mechanism for generating coherency in the light emission. Persons skilled in the art may also elect various approaches for coupling heat sinks on one or both sides of the gain chip so as to draw away heat.

The gallium and nitrogen containing (or GaN) substrate for the pump lasers may be of a c-plane (polar) crystalline orientation. In other embodiments, the bulk GaN substrate may be of a nonpolar or semipolar crystalline orientation. The crystalline orientation of the bulk GaN substrate may be selected depending on desired polarization and optical gain properties. Though polar crystalline orientation is known for providing spontaneous polarization, if increased polarization extinction ratio (“PER”) is desired, a nonpolar or semipolar GaN substrate crystalline orientation may be selected. If VCSEL pumping lasers are used, forming the VCSELs on a polar GaN substrate may not result in high polarization due to the in-plane crystallographic symmetry. Using nonpolar or semipolar GaN substrate instead may provide improved optical gains with greater PER-PER which may be greater than 90%, 99% or 99.9%. Polarization effects for the OPSL may be controlled using optics such as a cavity feedback mirror or other internal cavity optical elements such as birefringent filter.

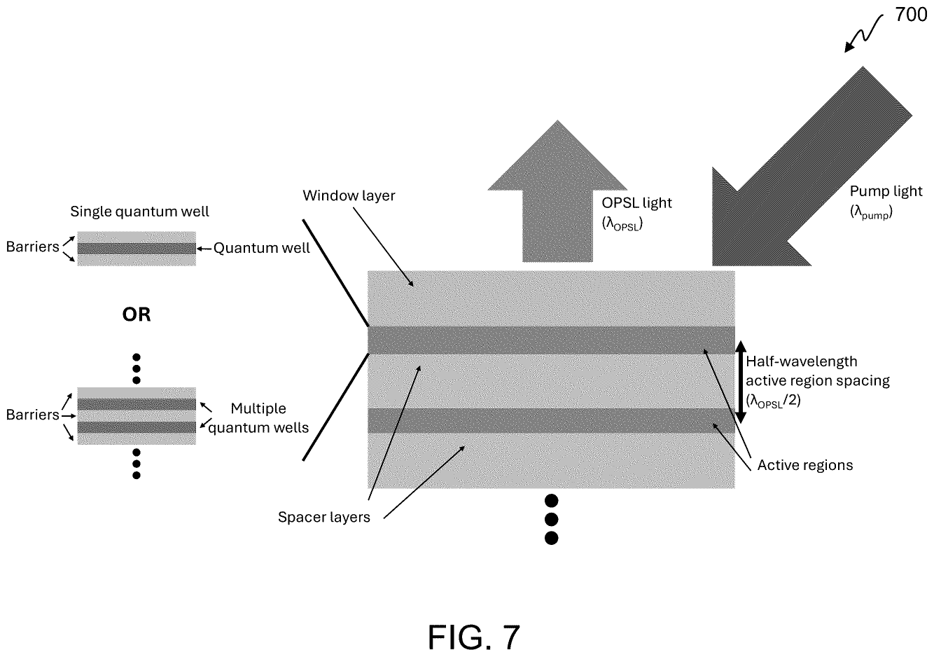

Referring to FIG. 7, the gain chip 700 may be fabricated on a GaN substrate which may be c-plane, semi-polar, or non-polar. Starting from the GaN substrate, a plurality of epitaxial thin films are formed. There may be a spacer region which may include one or more spacer layers which may be GaN but may be AlGaN or InGaN. On the spacer region there may be formed an active region which includes thin film layers comprising alternating films of barriers and quantum well layers which may be formed of variations on InGaN, GaN, AlGaInN, AlGaN, or other variants. The films may be doped with silicon, phosphorous, indium, aluminum, or other constituents, so as to modify the material strain effect while having certain photon absorption and band gap width characteristics. Upon formation of the active region, another spacer region may be formed. The pattern of spacer region, active region, spacer region may be repeated, with each active region distanced from each other according to a half-wavelength. Refractive index, light absorption, bandgap, and strain characteristics can be achieved. Note that because the gain chip will be pumped by the pumping lasers, the characteristics of the pumping lasers including spot size and distance from the gain chip.

A final layer fabricated on the gain chip may be a window layer if the barrier layers are being pumped. A window layer should be of a material (for example, AlGaN) having a lower refractive index compared with the gain chip. If the barrier layers are not being pumped, then instead of a window layer the top portion of the gain chip may be represented by a final spacer layer.

Note that the polarization of light emitting from the gain chip may be improved by using a grating structure such as distributed feedback (DFB), or there may be a Bragg reflector type grating.

In optimizing the wedged submount angle and distance from the emission end of the GaN pump lasers to the gain chip, the gain chip design considerations should be considered. Generally, a wedged submount angle of approximately 35 degrees to a horizontal may be preferred in some embodiments for several reasons in terms of design considerations, as well as practical considerations.

The resultant OPSL may include a lens for collimation and/or beam shaping. With the fine-tuning of the output beam, the OPSL may be used in a variety of applications requiring specific wavelengths and light quality including flow cytometry, fluorescence-based imaging, DNA sequencing, RGB/RYB projection, laser pumping, ultra-fast laser-based systems, and nitrogen vacancy useful for quantum applications such as quantum-based sensors for magnetometers and navigation.

The pump laser diode sources are preferably electrically powered. The OPSL needs only laser-based pumping, but further power output may be achieved by applying a power source to the OPSL.

Other embodiments and configurations may be used by those skilled in the art.

Additional description related to embodiments of the OPSL pumped with laser diodes is provided in the appended drawings.

The specific details of particular embodiments may be combined in any suitable manner without departing from the spirit and scope of embodiments described herein. However, other embodiments may be directed to specific features relating to each individual aspect, or specific combinations of these individual aspects.

The above description of exemplary embodiments has been presented for the purposes of illustration and description. It is not intended to be exhaustive or to limit the invention to the precise form described, and many modifications and variations are possible in light of the teachings above. The embodiments were chosen and described in order to best explain the principles and practical applications to thereby enable others skilled in the art to best utilize the various embodiments and with various modifications as are suited to the particular use contemplated.

A recitation of “a”, “an”, or “the” is intended to mean “one or more” unless specifically indicated to the contrary.

All patents, patent applications, publications, and descriptions mentioned here are incorporated by reference in their entirety for all purposes. None is admitted as being prior art.

1. An optically pumped solid state laser (OPSL) module, comprising:
a gain chip having a plurality of gallium and nitrogen containing thin films, the gain chip having a first side and an opposing second side;
a reflective mirror coupled to the second side of the gain chip;
one or more gallium and nitrogen containing laser diode sources positioned to provide optical pumping to said gain chip so as to generate a photonic emission output from the first side of the gain chip;
a coherence-generating reflecting mirror positioned relative to the gain chip so as to receive the photonic emission output from the first side of the gain chip such that the photonic emission incident on the coherence-generating reflecting mirror interacts with the reflective mirror so as to generate a coherent photonic emission emitted from the coherence-generating reflecting mirror;
a heat conducting member coupled to the gain chip; and
optics arranged to gather and transmit the coherent photonic emission.

2. The OPSL module of claim 1 wherein the reflective mirror includes a distributed Bragg reflector (DBR).

3. The OPSL module of claim 1 wherein the reflective mirror and the coherence-generating reflecting mirror are arranged so that the photonic emission reflected by the reflective mirror is incident on and reflected by the coherence-generating reflecting mirror.

4. The OPSL module of claim 1 wherein the reflective mirror is a coating of one or more reflective materials.

5. (canceled)

6. The OPSL module of claim 1 wherein the heat conducting member is a heat sink.

7. The OPSL module of claim 1 further comprising a plurality of gain chips and a plurality of laser diode sources, wherein the plurality of gain chips are arranged in an array and each of the plurality of laser diode sources pumps one of the plurality of gain chips.

8. (canceled)

9. An optically pumped solid state laser (OPSL) module, comprising:
a submount unit having one or more raised wedge portions and a center portion, a surface of each of the raised wedge portions extending at a positive angle to a surface of the center portion, and the center portion extending from a lower portion of the raised wedge portions;
one or more gallium and nitrogen containing pump laser diodes, each of the gallium and nitrogen containing pump laser diodes mounted on a different one of the raised wedge portions;
a gallium and nitrogen containing gain chip arranged on the center portion, the gallium and nitrogen containing gain chip comprising a series of alternating spacer and active regions so that optical pumping from the gallium and nitrogen containing pump laser diodes generates a photonic emission from the gallium and nitrogen containing gain chip, the spacer and active regions configured to provide a desired wavelength of the photonic emission, each active region spaced from others of the active regions based on a half-wavelength metric; and
one or more beam shaping optics each associated with one of the gallium and nitrogen containing pump laser diodes, wherein each of the beam shaping optics is arranged so that an emission from one of the gallium and nitrogen containing pump laser diodes mounted on one of the raised wedge portions extends through the beam shaping optic and onto an upper surface of the gallium and nitrogen containing gain chip.

10. The OPSL module of claim 9 wherein an upper surface of the center portion is substantially planar.

11. The OPSL module of claim 9 wherein the positive angle is an obtuse angle of about 145 degrees.

12. (canceled)

13. The OPSL module of claim 9 wherein a bottom surface of the gallium and nitrogen containing gain chip includes a distributed Bragg reflector (DBR).

14. The OPSL module of claim 9 further comprising a mirror arranged so that the photonic emission from the gallium and nitrogen containing gain chip emanates towards the mirror, and the mirror is configured to reflect the photonic emission to generate a coherent emission that is emitted from the mirror as a laser beam.

15.-16. (canceled)

17. The OPSL module of claim 9 further comprising a heat sink coupled to the submount unit.

18. (canceled)

19. The OPSL module of claim 9 wherein the center portion includes a reflector configured to reflect the photonic emission.

20. (canceled)

21. The OPSL module of claim 9 further comprising a means for tuning a wavelength of the photonic emission.

22.-23. (canceled)

24. The OPSL module of claim 9 further comprising a housing with walls and a transparent window.

25. The OPSL module of claim 9 further comprising a window and an upper mirror, the window configured to allow the photonic emission to pass therethrough, and the upper mirror arranged so that the photonic emission that passes through the window emanates towards the upper mirror, and the upper mirror is configured reflect the photonic emission to generate a coherent emission that is emitted from the mirror as a laser beam.

26. The OPSL module of claim 9 comprising at least two raised wedge portions each having one of the gallium and nitrogen containing pump laser diodes mounted thereto.

27.-29. (canceled)

30. The OPSL module of claim 9 further comprising a housing with walls and a window, wherein the window is configured to reflect the photonic emission to generate a coherent emission that is emitted from the window as a laser beam.

31.-37. (canceled)

38. An optically pumped solid state laser (OPSL) module, comprising:
a submount unit having a plurality of raised wedge portions and a center portion, a surface of each of the raised wedge portions extending at a positive angle to a surface of the center portion, and the center portion extending from a lower portion of the raised wedge portions;
a plurality of gallium and nitrogen containing pump laser diodes, each of the gallium and nitrogen containing pump laser diodes mounted on a different one of the raised wedge portions;
an N×M array of gallium and nitrogen containing gain chips arranged on the center portion, each of the gallium and nitrogen containing gain chips comprising a series of alternating spacer and active regions so that optical pumping from the gallium and nitrogen containing pump laser diodes generates a photonic emission from the gallium and nitrogen containing gain chips, the spacer and active regions configured to provide a desired wavelength of the photonic emission, each active region spaced from others of the active regions based on a half-wavelength metric; and
one or more beam shaping optics each associated with one of the gallium and nitrogen containing pump laser diodes, wherein each of the beam shaping optics is arranged so that an emission from one of the gallium and nitrogen containing pump laser diodes mounted on one of the raised wedge portions extends through the beam shaping optic and onto an upper surface of at least one of the gallium and nitrogen containing gain chips.

39. The OPSL module of claim 38 wherein the N×M array of gallium and nitrogen containing gain chips includes at least two gallium and nitrogen containing gain chips, and N is at least one and M is at least one.

40.-42. (canceled)
